(19) United States
(12) Patent Application Publication
(10) Pub. No.: US 2014/0023847 A1
(43) Pub. Date: Jan. 23, 2014

(54) POLYIMIDE FILM AND METAL LAMINATE USING SAME

(71) Applicants: Takuro Kochiyama, Ube-shi (JP); Eiji Masui, Ube-shi (JP); Keiichi Yanagida, Ube-shi (JP); Takeshi Uekido, Ube-shi (JP)

(72) Inventors: Takuro Kochiyama, Ube-shi (JP); Eiji Masui, Ube-shi (JP); Keiichi Yanagida, Ube-shi (JP); Takeshi Uekido, Ube-shi (JP)

(73) Assignee: UBE INDUSTRIES, LTD., Ube-shi (JP)

(21) Appl. No.: 14/008,320

(22) PCT Filed: Mar. 28, 2012
(86) PCT No.: PCT/JP2012/058264

§ 371 Date: Sep. 27, 2013

(30) Foreign Application Priority Data
Mar. 30, 2011 (JP) 2011-076875

(51) Int. Cl. H05K 1/03

(52) U.S. Cl. CPC H05K 1/036
USPC 428/220; 428/473.5; 428/458; 427/340

(57) ABSTRACT

A polyimide film having no foaming during heating or other problems, as well as a polyimide laminate-metal laminate in which the polyimide film and a metal layer are laminated. The polyimide film includes a polyimide layer (b), and a polyimide layer (a) laminated in contact with the polyimide layer (b), a side of the polyimide layer (b) which is not in contact with the polyimide layer (a) exhibits thermal fusion bondability, a side of the polyimide layer (a) which is not in contact with the polyimide layer (b) does not exhibit thermal fusion bondability, and the polyimide layer (a) includes a polyimide formed from a tetracarboxylic acid component containing 2,3,3′,4′-biphenyltetracarboxylic dianhydride and a diamine component.

### TECHNICAL FIELD

The present invention relates to a polyimide film and a metal laminate using the polyimide film.

### BACKGROUND ART

A polyimide film has been extensively used in the fields including electric/electronic devices and semiconductors because it has excellent heat resistance, chemical resistance, mechanical strength, electric properties, dimensional stability and so on. For example, a copper-clad laminate where a copper foil is laminated on one or both sides of a polyimide film is used as a material for an electronic component such as a flexible printed circuit board (FPC), a printed circuit board and a TAB tape.

For manufacturing the laminate, one of the methods for laminating a polyimide film with a metal foil is thermo-pressure-bonding a thermal fusion bondable polyimide film and a copper foil, to provide a laminate of the polyimide film and the copper foil.

Patent Reference No. 1 has disclosed a polyimide film, only one side of which has thermal fusion bondability. This polyimide film has a structure that a heat-resistant polyimide layer which does not have thermal fusion bondability is laminated to one side of a polyimide layer having thermal fusion bondability on its both sides. And, the above polyimide film is produced by applying a polyamic acid solution (coating liquid) comprising a composition to form a heat-resistant polyimide layer which does not have thermal fusion bondability, to one side of a self-supporting film.

### PRIOR ART REFERENCES

### Patent References

Patent Reference No. 1: Japanese Patent Laid-Open No. 2004-230670.

### SUMMARY OF THE INVENTION

### Problem to be Solved by the Invention

However, since the coating liquid comprising a composition as described in Patent Reference No. 1 exhibits poor water-permeability, foaming and white turbidness may occur in a film surface during heating, leading to reduction in productivity.

To solve the above problem, an objective of the present invention is to provide a polyimide film which is free from foaming during heating, a laminate formed by laminating the film with a metal foil, and a manufacturing process therefor.

### Means for Solving the Problem

The present invention relates to the following items.

1. A polyimide film comprising:

a polyimide layer (b), and

a polyimide layer (a) laminated in contact with said polyimide layer (b),

wherein

a side of said polyimide layer (b) which is not in contact with the polyimide layer (a) exhibits thermal fusion bondability,

a side of said polyimide layer (a) which is not in contact with the polyimide layer (b) does not exhibit thermal fusion bondability, and

said polyimide layer (a) comprises a polyimide formed from a tetracarboxylic acid component containing 2,3,3′,4′-biphenyltetracarboxylic dianhydride and a diamine component.

2. The polyimide film according to the above item 1, wherein said polyimide layer (b) has a multi-layer structure having a thermal fusion bondable polyimide layer and a heat-resistant polyimide layer.
3. The polyimide film according to the above item 1 or 2, wherein said polyimide layer (b) has a three-layer structure where the thermal fusion bondable polyimide layers are formed on both sides of the heat-resistant polyimide layer.
4. The polyimide film according to any one of the above items 1 to 3, wherein a content of 2,3,3′,4′-biphenyltetracarboxylic dianhydride in said tetracarboxylic acid component is 25 mol % or more.
5. The polyimide film according to any one of the above items 1 to 3, wherein a content of 2,3,3′,4′-biphenyltetracarboxylic dianhydride in said tetracarboxylic acid component is 50 mol % or more and 100 mol % or lower.
6. The polyimide film according to any one of the above items 2 to 5, wherein a total thickness of said polyimide layer (b) is 15 to 50 μm, a thickness of said heat-resistant polyimide layer is 10 to 40 μm, and a thickness of a single-layer in said thermal fusion bondable polyimide layer is 4 to 6 p.m.
7. The polyimide film according to any one of the above items 2 to 6, wherein said heat-resistant polyimide layer is formed from an acid component comprising 3,3′,4,4′-biphenyltetracarboxylic dianhydride and a diamine component comprising p-phenylenediamine.
8. A polyimide-metal laminate wherein the polyimide film having the polyimide layer (b) according to any one of the above items 1 to 7 and a metal layer are laminated, and wherein the side exhibiting thermal fusion bondablity of the polyimide layer (b) which is not in contact with the polyimide layer (a) directly contacts the metal layer.
9. A process for manufacturing a polyimide film, comprising:

producing a self-supporting film (b) by using a polyamic acid (b) for preparing a polyimide layer (b), both sides of which exhibits thermal fusion bondability;

applying a polyamic acid (a) obtained from an acid component comprising 2,3,3′,4′-biphenyltetracarboxylic dianhydride and a diamine component to only one side of said self-supporting film (b), to form a coated film; and

heating said coated film for imidization.

### Effect of the Invention

The present invention provides a polyimide film which is free from foaming during heating, a metal laminate formed by laminating the film with a metal foil, and a manufacturing process therefor. In a process for manufacturing a metal laminate using a polyimide film of the present invention, it can eliminate the necessity for the use of a release paper and the like, so that a metal laminate can be more efficiently produced with a lower cost than the prior art.

### BRIEF DESCRIPTION OF THE DRAWINGS

FIG. 1 illustrates an example of a structure of a polyimide film of the present invention.

FIG. 2 illustrates an example of a structure of a polyimide film of the present invention.

FIG. 3 schematically shows a T-peel jig for evaluating peel strength of an example of the present invention.

### EMBODIMENT FOR CARRYING OUT THE INVENTION

### <Structure of a Polyimide Film>

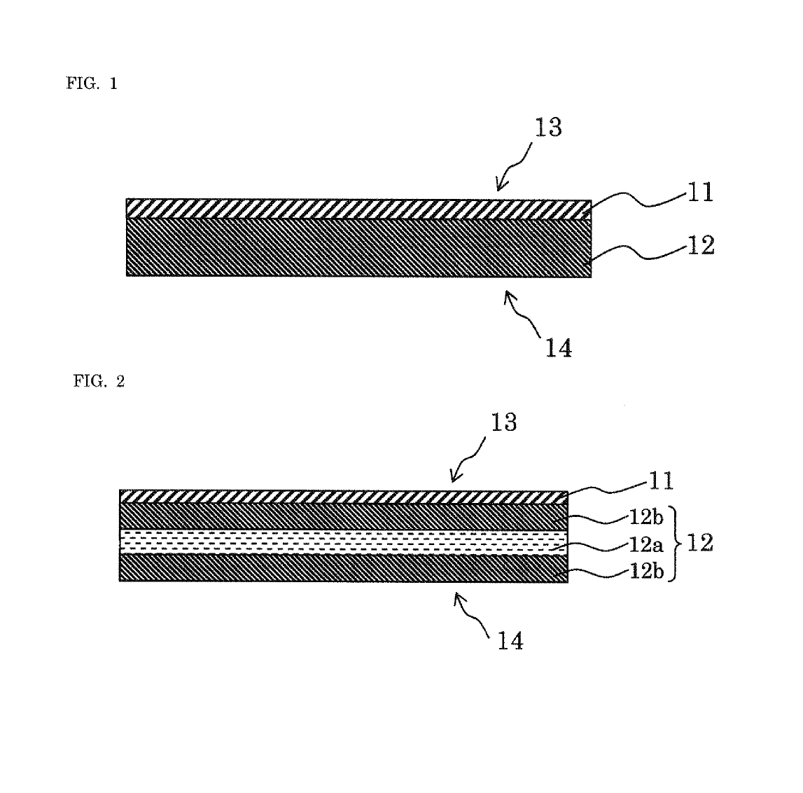

As shown in FIG. 1, a polyimide film of the present invention comprises a polyimide layer (b) (12) and a polyimide layer (a) (11) which is laminated in contact with the polyimide layer (b) (12). It is characterized in that in the polyimide layer (b) (12), the side 14 which is not in contact with the polyimide layer (a) (11) exhibits thermal fusion bondability, and in the polyimide layer (a) (11), the side 13 which is not in contact with the polyimide layer (b) (12) does not exhibit thermal fusion bondability, and the polyimide layer (a) (11) contains a polyimide formed from a tetracarboxylic acid component containing 2,3,3′,4′-biphenyltetracarboxylic dianhydride and a diamine component. Hereinafter, a polyimide layer (a) is sometimes referred to as “polyimide layer (a) not exhibiting thermal fusion bondability” or “layer (a)”, and a polyimide layer (b) is sometimes referred to as “polyimide layer exhibiting thermal fusion bondability”, “thermal fusion bondable polyimide layer (b)” or “layer (b)”.

The expression “exhibiting thermal fusion bondability” as used herein means that a softening point of the polyimide in the surface of the polyimide film is less than 350° C. A softening point is a temperature at which softening abruptly occurs during heating, and thus a softening point is Tg in an amorphous polyimide and a melting point in a crystalline polyimide. Hereinafter, having thermal fusion bondability is sometimes referred to as “being thermoplastic”. In addition, “not exhibiting thermal fusion bondability” indicates a polyimide in which a softening point of the surface of the polyimide film is 350° C. or higher. Hereinafter, “not exhibiting thermal fusion bondability” is sometimes referred to as “being not thermoplastic”.

In FIG. 1, the side 13 does not exhibit thermal fusion bondability while the side 14 exhibits thermal fusion bondability.

In the polyimide layer (b) exhibiting thermal fusion bondability, the whole layer (b) may be formed by a single-layer film of a thermal fusion bondable polyimide or have a laminate structure of two or more layers containing additional layers. Here, examples of such additional layers include a polyimide not exhibiting thermal fusion bondability, a thermal fusion bondable polyimide comprising a different composition and a layer other than a polyimide such as an adhesive. Among these, a laminate containing a heat-resistant polyimide layer (12a) which does not exhibit thermal fusion bondability as described later can be particularly suitably used because it is excellent in strength and dimensional stability.

In the polyimide layer (a) (11), at least the side 13 which is not in contact with the polyimide layer (b) (12) at least does not exhibit thermal fusion bondability. For the polyimide layer (a) not exhibiting thermal fusion bondability, the whole layer (a) can be formed by a single-layer film of a polyimide which does not exhibit thermal fusion bondability.

FIG. 2 shows an example in which a thermal fusion bondable polyimide layer (b) (12) has a three-layer structure; specifically, thermal fusion bondable polyimide layers (S2) (12b) are formed on both sides of a heat-resistant polyimide layer (S1) (12a) which is not thermoplastic. When a layer (b) is constituted in multi-layer, a boundary between each layer may be definite or may be a gradient layer where compositions are mixed. That is, the polyimide layer (12b) may form a region independent of (12a). The polyimide film shown in FIG. 2 has a four-layer structure consisting of the polyimide layer (b) (12) having a three-layer structure and a polyimide layer (a) (11).

For the polyimide layer (b) (12), the whole layer may be formed by a single-layer film of a thermal fusion bondable polyimide or the surface layers (12b) in both sides of the polyimide layer (12) may exhibit thermal fusion bondability. Alternatively, in the polyimide layer (12), only the side 14 (12b) which is not in contact with the polyimide layer (a) (11) may exhibit thermal fusion bondability. Among these, a laminate in which polyimide layers (12b) having a thermal fusion bondable polyimide are formed on both sides of a heat-resistant polyimide layer (12a) which does not exhibit thermal fusion bondability may be particularly suitably used because it is excellent in strength and dimensional stability.

A thickness of a polyimide film of the present invention is preferably, but not limited to, 7 μm to 100 μm, more preferably 10 μm to 50 μm.

In the present invention, a thickness of a polyimide layer (a) not exhibiting thermal fusion bondability is, for example, preferably, but not limited to, 0.2 to 3.0 μm, more preferably 0.3 to 2.0 μm, further preferably 0.5 to 1.2 μm.

A thickness of a thermal fusion bondable polyimide layer (b) is, for example, preferably, but not limited to, 4 to 100 μm, more preferably 10 to 75 μm.

For example, when a thermal fusion bondable polyimide layer (b) is formed in a three-layer structure as shown in FIG. 2, a thickness of a heat-resistant polyimide layer (S1) is preferably 3 to 70 μm, more preferably 8 to 50 μm, further preferably 8 to 40 μm, particularly preferably 8 to 38.2 μm. There are no particular restrictions to thickness of a thermal fusion bondable polyimide layer (S2) on one side of the heat-resistant polyimide layer (S1) or a thermal fusion bondable polyimide layer (S2) on the other side of the heat-resistant polyimide layer (S1), but preferably they have an almost equal thickness, and a total thickness of the layers (S2) in both sides is preferably 1 to 30 μm, more preferably 2 to 25 μm.

A thickness of the single thermal fusion bondable polyimide layer (S2) is preferably 0.5 to 15 μm, more preferably 1 to 12.5 μm.

In the case of a three-layer structure in which thermal fusion bondable polyimide layers (S2) are formed on both sides of the heat-resistant polyimide layer (S1), a total thickness of the thermal fusion bondable polyimide layer (b) is 15 to 50 μm, a thickness of a heat-resistant polyimide layer (S1) is 10 to 40 μm. When a single thermal fusion bondable polyimide layer (S2) has a thickness of 4 to 6 μm, a peeling property of the film is particularly good.

In terms of physical properties of a polyimide film of the present invention, a thermal shrinkage is preferably 0.05% or less. When a polyimide film is laminated with a metal foil, a linear expansion coefficient of the polyimide film (50 to 200° C.) is preferably close to a linear expansion coefficient of a metal foil laminated on a polyimide resin substrate. For example, when the metal foil is a copper foil, a linear expansion coefficient of a polyimide film (50 to 200° C.) is preferably 0.5×10⁻⁵ to 2.8×10⁻⁵ cm/cm/° C.

A polyimide film of the present invention is produced by a process described later, which is advantageous in that foaming and white turbidness due to heating are prevented and poor appearance or the like is improved in comparison with the prior art. When a metal foil is laminated on the side (14) exhibiting thermal fusion bondability of a polyimide film of the present invention to produce a single-sided metal foil laminate, the opposite side (13) does not exhibit thermal fusion bondability and has poor peel strength, so that it is not necessary to place a release material on the opposite side (side (13) in the case of the present invention) as in the prior art. Furthermore, when a polyimide film of the present invention is used in an electronic component or the like, problems such as its attachment to a device, a jig or the like during a production process can be avoided.

There will be described a polyimide constituting each polyimide layer.

### <Polyimide Layer (a) not Exhibiting Thermal Fusion Bondability>

A polyimide constituting a polyimide layer (a) not exhibiting thermal fusion bondability of the present invention is prepared from an acid component and a diamine component, and characterized in that the acid component contains 2,3,3′,4′-biphenyltetracarboxylic dianhydride (hereinafter, sometimes referred to as “a-BPDA”). A content of a-BPDA is more than 0 mol %, preferably 20 mol % or more, more preferably 25 mol % or more, further preferably 40 mol % or more, particularly preferably 50 mol % or more of the acid component, and may be 100 mol %. A content of a-BPDA in the acid component may be 50 mol % or more and 100 mol % or lower.

As a polyimide constituting a polyimide layer (a) which does not exhibit thermal fusion bondability, not only a completely non-thermoplastic resin which does not have a softening point, but also a hardly-thermoplastic resin having a softening point of 350° C. or higher, for example, higher than 350° C. may be used. As long as a combination having a softening point of higher than 350° C., an acid component other than a-BPDA and a diamine component may be combined.

Examples of an acid component other than a-BPDA for preparing a polyimide constituting a polyimide layer (a) include 3,3′,4,4′-biphenyltetracarboxylic dianhydride (s-BPDA), pyromellitic dianhydride and 1,4-hydroquinonedibenzoate-3,3′,4,4′-tetracarboxylic dianhydride.

A diamine component for preparing a polyimide constituting the polyimide layer (a) may be a diamine component containing at least one of compounds selected from the group consisting of p-phenylenediamine, 4,4′-diaminodiphenyl ether, 3,4′-diaminodiphenyl ether, m-tolidine and 4,4′-diaminobenzanilide, and contains these diamine components preferably at least in 70 mol % or more, more preferably 80 mol % or more, further preferably 90 mol % or more based on the total diamine components.

The examples of the combination of the acid component and the diamine component for obtaining a polyimide constituting the layer (a) of the polyimide film of the present invention include:

1) 2,3,3′,4′-biphenyltetracarboxylic dianhydride (a-BPDA), 3,3′,4,4′-biphenyltetracarboxylic dianhydride(s-BPDA), and p-phenylenediamine(PPD) and optionally 4,4′-diaminodiphenyl ether(DADE), wherein a-BPDA/s-BPDA(molar ratio) is, for example, preferably from 100/0 to 25/75 and wherein PPD/DADE(molar ratio) is preferably from 100/0 to 85/15;

2) 2,3,3′,4′-biphenyltetracarboxylic dianhydride (a-BPDA), 3,3′,4,4′-biphenyltetracarboxylic dianhydride (s-BPDA) and pyromellitic dianhydride (PMDA), and p-phenylenediamine (PPD) and optionally 4,4′-diaminodiphenyl ether (DADE), wherein a used amount of a-BPDA is as described above, s-BPDA/PMDA (molar ratio) is, for example, preferably from 0/100 to 90/10, and in case both PPD and DADE are used, PPD/DADE (molar ratio) is preferably, for example, 90/10 to 10/90;

3) 2,3,3′,4′-biphenyltetracarboxylic dianhydride (a-BPDA), pyromellitic dianhydride (PMDA), and p-phenylenediamine (PPD) and 4,4′-diaminodiphenyl ether (DADE), wherein a-BPDA/PMDA is preferably, for example, 100/0 to 10/90, DADE/PPD is preferably 90/10 to 10/90; and

4) 2,3,3′,4′-biphenyltetracarboxylic dianhydride (a-BPDA), 3,3′,4,4′-biphenyltetracarboxylic dianhydride (s-BPDA) and p-phenylene diamine (PPD), as main ingredient components (not less than 50 mole % in the total 100 mole %).

The above combination 1) is preferred since it is particularly excellent in heat resistance.

In the above 1) to 4), part or all of 4,4′-diaminodiphenyl ether (DADE) may be replaced with 3,4′-diaminodiphenyl ether or another diamine described later.

In particular, polyimides produced from a combination of the acid component and the diamine component described in 1) to 4) above are preferable because they exhibits excellent mechanical properties over a wide temperature range, long-term heat resistance, excellent hydrolysis resistance, a higher thermal-decomposition initiation temperature, a smaller thermal shrinkage and a smaller linear expansion coefficient, and excellent flame retardance. These may be used as a material for an electronic component such as a printed circuit board, a flexible printed circuit board and a TAB tape.

### <Other Acid Components>

As the acid component, that may be used for obtaining the polyimide constituting a layer (a), in addition to the acid components illustrated above, there can be used an acid dianhydride component such as 3,3′,4,4′-benzophenonetetracarboxylic dianhydride, bis(3,4-dicarboxyphenyl)ether dianhydride, bis(3,4-dicarboxyphenyl)sulfide dianhydride, bis(3,4-dicarboxyphenyl)sulfone dianhydride, bis(3,4-dicarboxyphenyl)methane dianhydride, 2,2-bis(3,4-dicarboxyphenyl)propane dianhydride, 2,2-bis(3,4-dicarboxyphenyl)-1,1,1,3,3,3-hexafluoropropane dianhydride, 2,2-bis[(3,4-dicarboxyphenoxy)phenyl]propane dianhydride or the like, in the ranges in which the characteristics of the present invention are not impaired.

### <Other Diamine Components>

As the diamine component that may be used for obtaining the polyimide constituting a layer (a), in addition to the diamine components illustrated above, there can be used a diamine component such as m-phenylene diamine, 2,4-toluene diamine, 3,3′-diaminodiphenyl sulfide, 3,4′-diaminodiphenyl sulfide, 4,4′-diaminodiphenyl sulfide, 3,3′-diaminodiphenyl sulfone, 3,4′-diaminodiphenyl sulfone, 4,4′-diaminodiphenyl sulfone, 3,3′-diaminobenzophenone, 4,4′-diaminobenzophenone, 3,4′-diaminobenzophenone, 3,3′-diaminodiphenyl methane, 4,4′-diaminodiphenyl methane, 3,4′-diaminodiphenyl methane, 2,2-di(3-aminophenyl)propane, 2,2-di(4-aminophenyl)propane, bis(aminophenoxy)benzenes such as 1,3-bis(4-aminophenoxy)benzene, 1,4-bis(4-aminophenoxy)benzene, 1,3-bis(3-aminophenoxy)benzene, 1,4-bis(3-aminophenoxy)benzene, 2,2-bis[4-(4-aminophenoxy)phenyl]propane, 4,4′-bis(4-aminophenoxy)biphenyl and the like, in the ranges in which the characteristics of the present invention are not impaired.

A polyimide layer (a) not exhibiting thermal fusion bondability may have a single-layer or a multi-layer having two-, three- or more layers. It may be multi-layered as long as the side of the outermost layer in a polyimide layer (a) that is not in contact with a polyimide layer (b) does not exhibit thermal fusion bondability.

### <Polyimide Layer (b) Exhibiting Thermal Fusion Bondability>

As described above, a polyimide layer (b) exhibiting thermal fusion bondability may be formed as a single-layer or milli-layer structure. When it is multi-layered, a three-layer laminate in which thermal fusion bondable polyimide layers are formed on both sides of a heat-resistant polyimide layer which is not exhibiting thermal fusion bondability may be particularly suitably used because it is excellent in strength and dimensional stability. A thermal fusion bondable polyimide described below constitutes the whole layer (b) when the polyimide layer (b) exhibiting thermal fusion bondability is single-layered, and it constitutes a thermal fusion bondable polyimide layer in the layer (b) when the layer (b) is multilayered.

In the description below, a thermal fusion bondable polyimide layer in a multi-layer-structure layer (b) is referred to as a thermal fusion bondable polyimide layer (S2) when it is needed to be distinguished from a whole thermal fusion bondable polyimide layer (b). In terms of common matters of a thermal fusion bondable polyimide layer in a single-layer and a thermal fusion bondable polyimide layer in a multi-layer, it is sometimes simply referred to as a “thermal fusion bondable polyimide layer”. In a multi-layer structure constituting a layer (b), a layer made of a heat-resistant polyimide is referred to as a heat-resistant polyimide layer (S1).

### <Thermal Fusion Bondable Polyimide>

A thermal fusion bondable polyimide is a polyimide having a softening point of lower than 350° C. as described above. A softening point is a temperature at which softening abruptly occurs, and a softening point corresponds to Tg in an amorphous polyimide and a melting point in a crystalline polyimide.

A thermal fusion bondable polyimide may be laminated with a metal foil preferably at a temperature of a softening point of the thermal fusion bondable polyimide or higher, more preferably at a temperature higher than the softening point by 20° C., further preferably at a temperature higher than the softening point by 30° C., particularly preferably at a temperature in a range of a temperature higher than a glass-transition temperature by 50° C. and 400° C. or lower, to form a polyimide-metal laminate.

As the thermal fusion bondable polyimide, there can be used those having at least one property below, those having at least two properties below {i.e., the combination of 1) and 2); 1) and 3); or 2) and 3)}, those having at least three properties below {i.e., the combination of 1), 2) and 3); 1), 3) and 4); 2), 3) and 4); 1), 2) and 4); or the like}, and particularly those having all properties below:

1) a peel strength after the polyimide of the laminate and a metal foil are bonded is 0.7 N/mm or more, and the retention ratio of a peel strength after heat treatment at 150° C. for 168 hours is 90% or more, further 95% or more and particularly 100% or more;

2) its glass transition temperature is from 130 to 330° C., or those that can be thermal fusion bondable between the thermal fusion bondable polyimides or between the thermal fusion bondable polyimide and a metal foil at 150° C. to 400° C., preferably 250° C. to 370° C.;

3) its tensile modulus is from 100 to 700 Kg/mm²; and

4) its linear expansion coefficient (50 to 200° C.) (MD) is from 13×10⁻⁶ to 50×10⁻⁶ cm/cm/° C.

The thermal fusion bondable polyimide is preferably selected from those that can perform thermal fusion bonding of the thermal fusion bondable polyimides each other and tightly-bonding of the thermal fusion bondable polyimide and the metal foil such as copper foil within a range from 250° C. or higher to 400° C. or lower, preferably from 270° C. to 370° C. This enables forming the laminate having an excellent heat resistance which is usable under a high temperature.

As a thermal fusion bondable polyimide, there can be used polyimide obtained from:

(1) an acid component containing at least one component selected from acid dianhydrides such as 3,3′,4,4′-biphenyltetracarboxylic dianhydride, 2,3,3′,4′-biphenyltetracarboxylic dianhydride, pyromellitic dianhydride, 3,3′,4,4′-benzophenonetetracarboxylic dianhydride, bis(3,4-dicarboxyphenyl)ether dianhydride, bis(3,4-dicarboxyphenyl)sulfide dianhydride, bis(3,4-dicarboxyphenyl)sulfone dianhydride, bis(3,4-dicarboxyphenyl)methane dianhydride, 2,2-bis(3,4-dicarboxyphenyl)propane dianhydride, 1,4-hydroquinone dibenzoate-3,3′,4,4′-tetracarboxylic dianhydride and the like, and preferably an acid component containing these acid components in an amount of at least not less than 70 mole %, further preferably not less than 80 mole % and more preferably not less than 90 mole %, and

(2) a diamine component containing at least one component selected from diamines such as 1,3-bis(4-aminophenoxy)benzene, 1,3-bis(3-aminophenoxy)benzene, 1,4-bis(4-aminophenoxy)benzene, 3,3′-diaminobenzophenone, 4,4′-bis(3-aminophenoxy)biphenyl, 4,4′-bis(4-aminophenoxy)biphenyl, bis[4-(3-aminophenoxy)phenyl]ketone, bis[4-(4-aminophenoxy)phenyl]ketone, bis[4-(3-aminophenoxy)phenyl]sulfide, bis[4-(4-aminophenoxy)phenyl]sulfide, bis[4-(3-aminophenoxy)phenyl]sulfone, bis[4-(4-aminophenoxy)phenyl]sulfone, bis[4-(3-aminophenoxy)phenyl]ether, bis[4-(4-aminophenoxy)phenyl]ether, 2,2-bis[4-(3-aminophenoxy)phenyl]propane, 2,2-bis[4-(4-aminophenoxy)phenyl]propane and the like as a diamine component, and preferably a diamine component containing these diamine components in an amount of at least not less than 70 mole %, further preferably not less than 80 mole % and more preferably not less than 90 mole %.

As the combination of the acid component and the diamine component that can be used for obtaining the thermal fusion bondable polyimide, there can be used polyimide obtained from:

(1) an acid component containing at least one component selected from acid dianhydrides such as 3,3′,4,4′-biphenyltetracarboxylic dianhydride and 2,3,3′,4′-biphenyltetracarboxylic dianhydride, and preferably an acid component containing these acid components in an amount of at least not less than 70 mole %, further preferably not less than 80 mole % and more preferably not less than 90 mole %; and

(2) a diamine component containing at least one component selected from diamines such as 1,3-bis(4-aminophenoxy)benzene, 1,3-bis(3-aminophenoxy)benzene, 4,4′-bis(3-aminophenoxy)biphenyl, bis[4-(3-aminophenoxy)phenyl]sulfone, bis[4-(3-aminophenoxy)phenyl]ether, 2,2-bis[4-(3-aminophenoxy)phenyl]propane, 2,2-bis[4-(4-aminophenoxy)phenyl]propane and the like as a diamine component, and preferably a diamine component containing these diamine components in an amount of at least not less than 70 mole %, further preferably not less than 80 mole % and more preferably not less than 90 mole %.

As the diamine component that may be used for obtaining the thermal fusion bondable polyimide, in addition to the diamine components illustrated above, there can be used a diamine component such as p-phenylene diamine, m-phenylene diamine, 2,4-toluene diamine, 3,4′-diaminodiphenyl ether, 3,3′-diaminodiphenyl sulfide, 3,4′-diaminodiphenyl sulfide, 4,4′-diaminodiphenyl sulfide, 3,3′-diaminodiphenyl sulfone, 3,4′-diaminodiphenyl sulfone, 4,4′-diaminodiphenyl sulfone, 3,3′-diaminobenzophenone, 4,4′-diaminobenzophenone, 3,4′-diaminobenzophenone, 3,3′-diaminodiphenyl methane, 4,4′-diaminodiphenyl methane, 3,4′-diaminodiphenyl methane, 2,2-di(3-aminophenyl)propane, 2,2-di(4-aminophenyl)propane and the like, in the ranges in which the characteristics of the present invention are not impaired.

A polyimide layer (b) exhibiting thermal fusion bondability may be made of a thermal fusion bondable polyimide alone or may have a multi-layer structure further containing a layer made of another component such as a heat-resistant polyimide layer which does not exhibit thermal fusion bondability. Among these, a structure in which thermal fusion bondable polyimide layers (S2) are laminated on both sides of a heat-resistant polyimide layer (S1) (FIG. 2) is particularly preferable, and the structure will be described below as an example.

### <Heat-Resistant Polyimide Layer (S1)>

As the heat resistant polyimide of the heat resistant polyimide layer (S1), there can be used those having at least one of the characteristics described below, those having at least two of the characteristics described below [combination of 1) and 2), 1) and 3), or 2) and 3)], or in particular those having all the characteristics described below.

1) As a single polyimide film, those with a glass transition temperature not less than 300° C., preferably a glass transition temperature not less than 330° C. and more preferably impossible to identify.
2) As a single polyimide film, those wherein its linear expansion coefficient (50 to 200° C.) (MD) should be close to a thermal expansion coefficient of a metal foil to be laminated,
3) As a single polyimide film, those with a tensile modulus (MD, ASTM-D882) not less than 300 kg/mm², preferably not less than 500 kg/mm² and furthermore not less than 700 kg/mm².

As the heat resistant polyimide, there can be used polyimide obtained from the combination of:

(1) an acid component containing at least one selected from 3,3′,4,4′-biphenyltetracarboxylic dianhydride, pyromellitic dianhydride and 1,4-hydroquinone dibenzoate-3,3′,4,4′-tetracarboxylic dianhydride, and preferably an acid component containing these acid components in an amount of at least not less than 70 mole %, further preferably not less than 80 mole % and more preferably not less than 90 mole %; and

(2) a diamine component containing at least one selected from p-phenylene diamine, 4,4′-diaminodiphenyl ether, 3,4′-diaminodiphenyl ether, m-tolidine and 4,4′-diamino benzanilide, and preferably a diamine component containing these diamine components in an amount of at least not less than 70 mole %, further preferably not less than 80 mole % and more preferably not less than 90 mole %.

Examples of the combination of the acid component and the diamine component for obtaining the heat resistant polyimide include:

1) 3,3′,4,4′-biphenyltetracarboxylic dianhydride(s-BPDA), and p-phenylenediamine(PPD) and optionally 4,4′-diaminodiphenyl ether(DADE), wherein PPD/DADE(molar ratio) is preferably from 100/0 to 85/15;

2) 3,3′,4,4′-biphenyltetracarboxylic dianhydride and pyromellitic dianhydride(PMDA), and p-phenylenediamine and optionally 4,4′-diaminodiphenyl ether, wherein BPDA/PMDA is preferably 0/100 to 90/10, and in case both PPD and DADE are used, PPD/DADE is preferably, for example, 90/10 to 10/90;

3) pyromellitic dianhydride, and p-phenylenediamine and 4,4′-diaminodiphenyl ether, wherein DADE/PPD is preferably 90/10 to 10/90; and

4) 3,3′,4,4′-biphenyltetracarboxylic dianhydride and p-phenylene diamine, as main ingredient components (not less than 50 mole % in the total 100 mole %).

The above combination 1) is preferred since it is particularly excellent in heat resistance.

In the above 1) to 4), part or all of 4,4′-diaminodiphenyl ether (DADE) may be replaced with 3,4′-diaminodiphenyl ether depending on the purpose.

Furthermore, preparation of a heat-resistant polyimide in a heat-resistant polyimide layer (S1) may comprise, as an acid component and a diamine component, one or more selected from the compounds listed as “other acid components” and “other diamine components” described in the explanation for the polyimide layer (a) not exhibiting thermal fusion bondability and 2,3,3′,4′-biphenyltetracarboxylic dianhydride (a-BPDA) in the ranges in which the desired characteristics of the present invention are not impaired.

Examples of a method for producing a polyimide constituting each of the above polyimide layers include the method comprising reacting an acid component with a diamine component to synthesize a polyimide precursor, preparing a self-supporting film using the polyimide precursor, and then imidizing the self-supporting film by, for example, heating. It will be detailed below.

### <Preparation Process of a Polyimide Precursor Solution>

First, the acid component and the diamine component described above are reacted in an organic solvent, for example, at a temperature of about 100° C. or lower, particularly 20 to 60° C., to give a polyamic acid (hereinafter, sometimes referred to as “polyimide precursor”). A polyimide precursor may be synthesized by known methods, for example, by random-polymerizing or block-polymerizing substantially equimolar amounts of an acid component such as an aromatic tetracarboxylic dianhydride and an diamine component in an organic solvent. Alternatively, two or more polyimide precursors in which either of these two components is excessive may be prepared, and subsequently, these polyimide precursor solutions may be combined and then mixed under reaction conditions. The polyimide precursor solution thus obtained may be used without any treatment, or may be used after removing or adding a solvent, if necessary, for the preparation of a self-supporting film.

Furthermore, in the case that polyimide having an excellent solubility is used, the organic solvent solution of the polyimide can be obtained by heating the polyimide precursor solution at 150 to 250° C., or adding an imidization agent to perform reaction at not more than 150° C., particularly from 15 to 50° C., and followed by evaporating the solvent after imide-cyclizing, or followed by precipitation in a poor solvent to give powder, and dissolving the powder in the organic solution.

Examples of an organic solvent for the polyimide precursor solution include N-methyl-2-pyrrolidone, N,N-dimethylformamide, N,N-dimethylacetamide and N,N-diethylacetamide. These organic solvents may be used alone or in combination of two or more.

The polyimide precursor solution may contain an imidization catalyst, an organic phosphorous-containing compound, a fine particle such as an inorganic fine particle and an organic fine particle, and the like, if necessary.

Examples of the imidization catalyst include substituted or unsubstituted nitrogen-containing heterocyclic compounds, N-oxide compounds of the nitrogen-containing heterocyclic compounds, substituted or unsubstituted amino acid compounds, hydroxyl-containing aromatic hydrocarbon compounds, and aromatic heterocyclic compounds. Particularly preferable examples of the imidization catalyst include lower-alkyl imidazoles such as 1,2-dimethylimidazole, N-methylimidazole, N-benzyl-2-methylimidazole, 2-methylimidazole, 2-ethyl-4-methylimidazole and 5-methylbenzimidazole; benzimidazoles such as N-benzyl-2-methylimidazole; and substituted pyridines such as isoquinoline, 3,5-dimethylpyridine, 3,4-dimethylpyridine, 2,5-dimethylpyridine, 2,4-dimethylpyridine and 4-n-propylpyridine. The amount of the imidization catalyst to be used is preferably about 0.01 to 2 equivalents, particularly preferably about 0.02 to 1 equivalents relative to the amide acid unit in a polyamide acid. When the imidization catalyst is used, the polyimide film obtained may have improved properties, particularly extension and edge-cracking resistance.

When chemical imidization is intended, generally, a chemical imidization agent of the combination of a dehydration-ring closure agent and an organic amine is mixed in the polyimide precursor solution. The examples of dehydration-ring closure agent include, for example, dicyclohexylcarbodiimide and acid anhydride such as acetic anhydride, propionic anhydride, valeric anhydride, benzoic anhydride, trifluoroacetic anhydride; and the examples of organic amine include, for example, picoline, quinoline, isoquinoline, pyridine and the like; but not limited to these.

There are no particular restrictions to the polyimide precursor solution, so long as it may be cast on a support and converted into a self-supporting film which may be peeled from the support and be stretched in at least one direction in the subsequent step. The kind, polymerization degree and concentration of the polymer, and the kind and concentration of an additive which may be added to the solution, if necessary, and the viscosity of the solution may be appropriately selected.

The concentration of the polyimide precursor in the polyimide precursor solution is preferably 5 to 30 mass %, more preferably 10 to 25 mass %, and further preferably 15 to 20 mass %. Viscosity of the polyimide precursor solution is preferably 100 to 10000 poise, more preferably 400 to 5000 poise, further preferably 1000 to 3000 poise. In this way, the polyimide precursor solution in which additive addition or viscosity control has been completed is referred to as dope.

### <Production Process for a Polyimide Film>

There are no particular restrictions to a process for producing a polyimide film of the present invention as long as the polyimide layer (a) not exhibiting thermal fusion bondability is formed on only one side of the polyimide layer (b) exhibiting thermal fusion bondability. An example of a process for producing a polyimide film of the present invention is a process wherein a polyimide precursor for a polyimide layer (b) exhibiting thermal fusion bondability is used to form a self-supporting film, applying a solution of a polyimide precursor for a polyimide layer (a) not exhibiting thermal fusion bondability to one side of the film, and then drying and imidizing the film. There will be described below a process for producing a polyimide film when a polyimide layer (b) exhibiting thermal fusion bondability has a three-layer structure consisting of {a layer made of a polyimide exhibiting thermal fusion bondability (S2)/a heat-resistant polyimide layer (S1)/a layer made of a polyimide exhibiting thermal fusion bondability (S2)}.

### <Production of the Self-Supporting Film>

First, the self-supporting film for the polyimide layer exhibiting thermal fusion bondability (b) is produced. The self-supporting film for forming the thermal fusion bondable polyimide layer (b) may be obtained preferably by a method (i) or (ii), i.e.:

(i) by the coextrusion-flow-casting film formation method (also being simply referred to as multi-layer extrusion method), the dope liquid of the heat resistant polyimide (S1) and the dope liquid of the thermal fusion bondable polyimide (S2) are laminated and dried to obtain a self-supporting film (gel film), or

(ii) the dope liquid of the heat resistant polyimide (S1) is flow-cast on a support, and dried to give a self-supporting film, and next, on both sides thereof, the dope liquid of the thermal fusion bondable polyimide (S2) is applied and dried to give a self-supporting film.

For the coextrusion method, there may be used a well-known method, for example, a method described in the Japanese Laid-open Patent Publication No. H03-180343 (Japanese Kokoku Patent Publication No. H07-102661).

For example, the dope of the heat resistant polyimide (S1) and the solution of a polyamic acid for the thermal fusion bondable polyimide layer (S2) are supplied to a three-layer extrusion molding die so that the thickness of the heat resistant polyimide (S1 layer) is 3 to 70 μm and the thickness of the thermal fusion bondable polyimide (S2 layer) on both sides is 1 to 30 μm in total, and by a three-layer coextrusion method this is flow-cast and applied on a support surface such as a stainless mirror surface and a stainless belt surface, and at 100 to 200° C., a self-supporting film can be obtained in a semi-cured state or a dried state before the semi-curing. This semi-cured state or the state before the semi-curing means a self-supporting state by heating and/or chemical imidization.

Next, a solution of a polyimide precursor for a polyimide layer (a) not exhibiting thermal fusion bondability is uniformly applied and distributed to only one side of a heat-dried self-supporting film for the thermal fusion bondable polyimide layer (b) in such a manner that a thickness that a thickness of the polyimide layer (a) not exhibiting thermal fusion bondability is 0.2 to 3 μm, by an application method such as gravure coating, screen coating and dipping, to give a coated film.

This coated film may be, for example, processed as described below. The coated film is dried preferably at a drying temperature of 50 to 180° C., particularly preferably 60 to 160° C., further preferably 70 to 150° C., preferably for 0.1 to 20 min, more preferably 0.2 to 15 min, to form a self-supporting film after application.

In the self-supporting film after application obtained, heating loss is preferably about 25 to 60% by mass and particularly preferably from 30 to 50% by mass.

The heating loss of the above self-supporting film refers to a value obtained by the following equation from the weight W1 measured before drying and the weight W2 measured after drying when the object film is dried at 420° C. for 20 minutes.

Heating Loss(% by mass)={(W1−W2)/W1}×100

Furthermore, the imide conversion ratio of the above self-supporting film is obtained by the method using a Karl Fischer's moisture meter as described in the Japanese Laid-open Patent Publication No. H09-316199.

### <Imidization>

Then, following the above-mentioned drying step, the self-supporting film is continuously or intermittently dried and heat-treated, in a condition in which at least a pair of side edges of the self-supporting film is fixed by a fixing equipment capable of continuously or intermittently moving together with the self-supporting film, at a high temperature higher than the drying temperature, preferably within a range of 200 to 550° C. and particularly preferably within a range of 300 to 500° C. preferably for 1 to 100 minutes and particularly 1 to 10 minutes. The polyimide film having thermal fusion bondability of the present invention may be formed by sufficiently removing the solvent or the like from the self-supporting film and at the same time sufficiently imidizing the polymer constituting the film so that the contents of volatile components consisting of organic solvents and generated water in the polyimide film to be finally obtained is preferably not more than 1 weight %.

The fixing equipment of the self-supporting film preferably used herein is, for example, equipped with a pair of belts or chains having a plurality of pins or holders at even intervals, along both side edges in the longitudinal direction of the solidified film supplied continuously or intermittently, and is able to fix the film while the pair of belts or chains are continuously or intermittently moved with movement of the film. In addition, the fixing equipment of the above solidified film may be able to extend or shrink the film under heat treatment with a suitable elongation percentage or shrinkage ratio in a lateral direction or a longitudinal direction (particularly preferably from about 0.5 to 5% of elongation percentage of shrinkage ratio).

Incidentally, the polyimide film having thermal fusion bondability on only one side particularly having excellent dimensional stability may be obtained by heat-treating the polyimide film having thermal fusion bondability on only one side produced in the above step again under low or no tension of preferably not higher than 4N and particularly preferably not higher than 3N at a temperature of 100 to 400° C. preferably for 0.1 to 30 minutes. In addition, the thus-produced lengthy polyimide film may be rewound in a roll form by an appropriate known method.

Heating treatment may be performed by using various known equipments such as a hot air furnace, an infrared furnace or the like.

Instead of the above three-layer coextrusion method, a polyimide film of the present invention may be produced by a four-layer coextrusion method using a solution of a polyimide precursor for a polyimide layer (a) not exhibiting thermal fusion bondability and each solution of a polyimide precursor for three layers (S2/S1/S2) constituting the polyimide layer (b) exhibiting thermal fusion bondability.

Thus, there is provided a polyimide film having a structure of {a polyimide layer (a) not exhibiting thermal fusion bondability/a thermal fusion bondable polyimide layer (S2)/a heat-resistant polyimide layer (S1)/a thermal fusion bondable polyimide layer (S2 layer)}, only one side of which exhibits thermal fusion bondability.

### <Metal Laminates>

A metal foil as a metal layer may be laminated on the side exhibiting thermal fusion bondability of a polyimide film of the present invention. Thus, a metal laminate in which the polyimide film and the metal layer are laminated can be provided. Examples of a metal foil which may be used in this invention include, but not limited to, metals including copper and copper alloys such as an electrolytic copper foil and a rolled copper foil, aluminum and aluminum alloys, stainless steel, nickel and nickel alloys (42 alloy and the like). A thickness of the metal foil is preferably, but not limited to, 1 to 100 μm, more preferably 2 to 50 μm, further preferably 3 to 35 μm, further preferably 6 to 25 μm, particularly preferably 8 to 20 μm. The metal foil is particularly preferably selected from copper and copper alloys such as an electrolytic copper foil and a rolled copper foil.

When a thin metal foil (for example, a thickness of 1 to 8 μm, preferably 2 to 8 μm) is used, a metal foil on which a protective foil (for example, a carrier foil) is laminated for reinforcing and protecting the metal foil may be used. There are no particular restrictions to a material for a protective foil (carrier foil) as long as it can be laminated with a metal foil such as an ultrathin copper foil and can reinforce and protect it; examples which may be used include an aluminum foil, a copper foil and a resin foil whose surface is metal-coated. There are no particular restrictions to a thickness of a protective foil (carrier foil) as long as the foil can reinforce a thin metal foil, and it is preferably 10 to 200 μm, further preferably 12 to 100 μm, particularly preferably 15 to 75 μm.

A protective foil (carrier foil) may have any form as long as it is planarly laminated with an ultrathin metal foil such as an ultrathin copper foil.

A protective foil (carrier foil) laminated with a metal foil such as an ultrathin copper foil is processed in a continuous process and the bonding structure with a metal foil is kept at least until the end of production of a metal-foil laminated polyimide resin substrate, for facilitating handling.

Examples of method for removing a protective foil (carrier foil) from a metal foil such as copper foil include:

(1) peeling the protective foil (carrier foil) after laminating a metal foil having a protective foil (carrier foil) on a polyimide film, and

(2) etching off the protective foil (carrier foil) after laminating a metal foil having a protective foil (carrier foil) on a polyimide film.

For an electrolytic copper foil having a carrier foil, a copper component to be an electrolytic copper foil is electrodeposited on the surface of the carrier foil, and therefore, the carrier foil must be at least electrically conductive.

### <A Method for Producing Metal Laminate>

When the metal foil and the polyimide film having thermal fusion bondability on the only one side are laminated, a heating machine, a compression machine and a thermo-compression machine may be used, and preferably a heating or compression condition is appropriately selected depending on materials to be used. Although the production process is not particularly limited as long as continuous or batch laminating is possible, it is preferably carried out continuously by using a roll laminator, a double-belt press or the like. The adhesion side of the metal foil and/or the side of the polyimide film which exhibits thermal fusion bondability may be surface-treated by, for example, application of a silane coupling agent.

As an example of the method producing the single-sided metal foil laminate, the following method is exemplified. That is, a lengthy polyimide film having thermal fusion bondability on the only one side and metal foil are plied so that the metal foil and the side having fusion bondability of the polyimide film are faced each other. They are preferably pre-heated at about 150 to 250° C., particularly at a temperature higher than 150° C. and 250° C. or lower for about 2 to 120 seconds in line immediately before introducing in the machine by using a pre-heater such as a hot-air blower or an infrared heating machine. By using a pair of fusion bonding rolls or a double-belt press, they are thermal fusion bonded under pressure, wherein a temperature in a heating and fusion-bonding zone of the fusion-bonding rolls or the double-belt press is in a range from a temperature higher than a glass transition temperature by 20° C. or more of polyimide, further in a range from a temperature higher than a glass transition temperature by 30° C. or more, and particularly in a range from a temperature higher than a glass transition temperature by 50° C. or more, each up to 400° C. In particular, in the case of a double-belt press, the laminate is successively cooled while being pressed in a cooling zone. The laminate is suitably cooled to a temperature in a range from a temperature lower than the glass transition temperature of the polyimide having thermal fusion bondability by 20° C. or more, particularly by 30° C. or more, to 110° C., preferably to 115° C., more preferably to 120° C., and thus the lamination is completed, and the laminate is rewound in a roll form. Thus, the polyimide film exhibits the thermal fusion bondability on the only one side and its side having a thermal fusion bondability and the metal foil are directly-contacted and laminated, and thereby the single-sided metal foil laminate can be obtained.

As another aspect of a process for producing a metal laminate, two pairs of a combination of polyimide film of the present invention and a metal foil are continuously fed to a double belt press, wherein only one side of the polyimide film exhibits thermal fusion bondability, and wherein the polyimide film and the metal foil are continuously fed to the double belt press in such a manner that the sides not exhibiting thermal fusion bondability of the polyimide layers are inside and the metal foils are outside. The two pairs are simultaneously heated as described in the above aspect, thermally fusion bonded under pressure and then cooled. Then, the two laminates are separated by peeling and separately winded. This process can provide a long single-sided metal-foil laminate and it is preferable in the light of productivity.

Since a polyimide film of the present invention has one side which does not exhibit thermal fusion bondability, in any of the above production processes, when laminating a metal foil, it is not necessary to intervene a release material between the outermost layer of a polyimide film and a belt.

The pre-heating of the polyimide film before thermo-fusion bonding is effective to prevent the occurrence of defective appearance due to foaming in the laminate after thermo-fusion bonding.

The double-belt press can perform heating to high temperature and cooling down while applying pressure, and a hydrostatic type one using a heat carrier is preferable.

In the production of the single-sided metal foil laminate, lamination is carried out preferably at a drawing rate of 1 m/min or more by thermo-fusion bonding and cooling under pressure using a double-belt press. Thus-obtained laminate is continuously long and has a width of about 400 mm or more, particularly about 500 mm or more, and high adhesion strength (the peel strength of the metal foil and the polyimide film is not less than 0.7 N/mm, and the holding ratio of the peel strength is not less than 90% after heating treatment at 150° C. for 168 hours), and further has good appearance so that substantially no wrinkles are observed on the metal foil surface.

In the production of the single-sided metal foil laminates, lamination may be carried out by thermo-fusion bonding and cooling under pressure while placing protectors between outermost layers at both sides and the belts (i.e., two sheets of protectors).

For the protector, its material is not particularly limited for use as long as it is not thermo-fusion bondable to the polyimide layer (a) not exhibiting thermal fusion bondability and metal foil in the production of the laminates and has a good surface smoothness. The preferred examples thereof include metal foil, particularly copper foil, stainless foil, aluminum foil, and high heat resistant polyimide film (Upilex S, manufactured by Ube Industries, Ltd., Kapton H manufactured by DuPont-TORAY Co., Ltd.) and the like having about 5 to 125 μm in thickness, and preferably Upilex S, manufactured by Ube Industries.

The above description shows that,

when a thermal fusion bondable polyimide layer (b) has a three-layer structure, a polyimide film having a structure of {a polyimide layer (a) not exhibiting thermal fusion bondability/a layer made of a thermal fusion bondable polyimide (S2)/a layer made of a heat-resistant polyimide (S1)/a layer made of a thermal fusion bondable polyimide (S2)}, only one side of which exhibits thermal fusion bondability, can be formed and thus,

a single-sided metal-foil laminate having a structure of {a polyimide layer (a) not exhibiting thermal fusion bondability/a layer made of a thermal fusion bondable polyimide (S2)/a layer made of a heat-resistant polyimide (S1)/a layer made of a thermal fusion bondable polyimide (S2)/a metal foil} can be produced; or

when a thermal fusion bondable polyimide layer (b) has a single-layer structure, a single-sided thermal fusion bondable polyimide film having a two-layer structure of {a polyimide layer (a) not exhibiting thermal fusion bondability/a thermal fusion bondable polyimide layer (b)} can be formed and thus,

a laminate having a structure of {a polyimide layer (a) not exhibiting thermal fusion bondability/a thermal fusion bondable polyimide layer (b)/a metal foil} can be produced.

Alternatively, a single-layer structure of a thermal fusion bondable polyimide layer (b) or a three-layer-structure of {a thermal fusion bondable polyimide layer (S2)/a heat-resistant polyimide layer (S1)/a thermal fusion bondable polyimide layer (S2)}, and a polyimide layer (a) not exhibiting thermal fusion bondability can be directly formed on a metal foil. For example, on a metal foil is casted or applied each polyimide precursor solution prepared as described above in such a manner that the polyimide layer (a) not exhibiting thermal fusion bondability becomes the uppermost layer, which can be imidized by heating. As the method for casting or applying the polyimide precursor solution, for example, the multilayer extrusion method as described above may be employed, and the heating conditions for imidization may be those for producing the above film.

In the present invention, when a polyimide film is laminated with a copper foil, it is not necessary to place a release paper or the like on the side which is not laminated with the copper foil, so that a polyimide copper-clad laminate can be produced at low cost. Furthermore, since it is not necessary to remove a release paper when a polyimide copper-clad laminate is used, the problem of deterioration in processability can be eliminated, resulting in improvement in a yield of a laminate. Furthermore, it can eliminate the problem that a polyimide layer adheres to an apparatus during the step of mounting electronic elements, resulting in efficient mounting of electronic elements.

### EXAMPLES

The present invention will be further detailed with reference to Examples. The present invention is, however, not limited to these examples below.

In the examples below, a polyimide film was evaluated as follows.

### (Visual Observation)

Samples were compared by visual observation with reference to a sample which was not coated (uncoated sample). Evaluation criteria are as follows.

Good: The sample had appearance equivalent to an uncoated sample.

Slightly devitrified: The sample was transparent but slight white-turbid in a surface in comparison with an uncoated sample.

Overall foaming: The swelling due to foaming was observed.

### (HAZE)

Measured using a Haze Computer HZ-2 manufactured by Suga Test Instruments Co., Ltd.

### (Evaluation of Peeling Property)

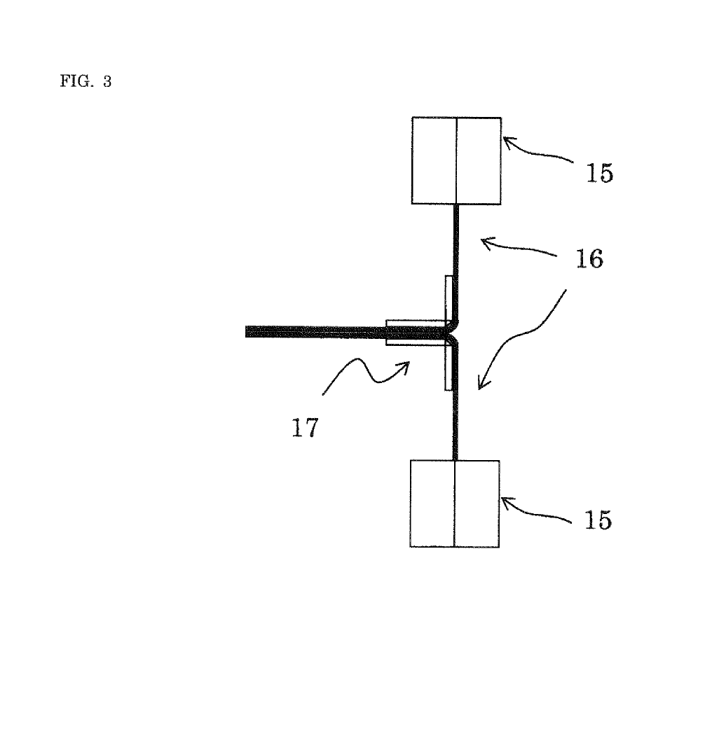

The films were placed in such a manner that the sides not exhibiting thermal fusion bondability were in contact with each other, and the sample was preheated and then laminated under the conditions of a heating temperature: 340° C. (preset), a pressure-bonding pressure: 30 kgf/cm² and a pressure-joining time: 1 min. Using a T-peel jig shown in FIG. 3, a sample having a width of 50 mm was measured for an MD direction and a T-peel strength at a cross-head speed of 50 min/min in accordance with JIS C6471.

Evaluation criteria are as follows.

∘∘: The sample was spontaneously peeled.

∘: The T-peel strength was 5 gf/cm or less.

Δ: The T-peel strength was 30 gf/cm or less.

### Example 1

A polyimide film having a structure shown in FIG. 2 was produced as described below.

### (Preparation of a Dope (Coating Solution) for a Polyimide not Exhibiting Thermal Fusion Bondability)

A coating solution 1 for forming a layer not exhibiting thermal fusion bondability (a) (11 in FIG. 2) was prepared. In a reaction vessel equipped with a stirrer and a nitrogen inlet tube, were charged N,N-dimethylacetamide (DMAc) and then p-phenylenediamine (PPD) and 2,3,3′,4′-biphenyltetracarboxylic dianhydride (a-BPDA) in a molar ratio of 1:1 in such an amount that a monomer concentration is 5% (% by weight, the same applies hereinafter). After completing addition, the reaction was continued for 3 hours keeping the system at 40° C. The resulting polyamic acid solution (coating solution 1) was a yellow liquid in which a solution viscosity at 25° C. was about 0.1 poise.

### (Preparation of a Dope for a Heat-Resistant Polyimide)

A dope for a heat-resistant polyimide for constituting a heat-resistant polyimide layer (S1) (12a in FIG. 2) was prepared. In N,N-dimethylacetamide, were added para-phenylenediamine (PPD) and 3,3′,4,4′-biphenyltetracarboxylic dianhydride (s-BPDA) in a molar ratio of 1000:998 in such amounts that a monomer concentration was 18% (% by weight, the same applies hereinafter), and then the mixture were reacted at 50° C. for 3 hours. The resulting polyamic acid solution (a dope for a heat-resistant polyimide) had a solution viscosity of about 1680 poise at 25° C.

### (Preparation of a Dope for a Thermal Fusion Bondable Polyimide)

A dope for a thermal fusion bondable polyimide for constituting a thermal fusion polyimide layer (S2)(12b in FIG. 2) was prepared. In N,N-dimethylacetamide, were added 1,3-bis(4-aminophenoxy)benzene (TPE-R) and then 2,3,3′,4′-biphenyltetracarboxylic dianhydride (a-BPDA) and 3,3′,4,4′-biphenyltetracarboxylic dianhydride (s-BPDA) in a molar ratio of 1000:200:800 in such amounts that a monomer concentration was 18%, and then 0.5% by weight of triphenyl phosphate based on a monomer weight, and the mixture was reacted at 40° C. for 3 hours. The resulting polyamic acid solution (a dope for a thermal fusion bondable polyimide) has a solution viscosity of about 1680 poise at 25° C.

(Production of a Polyimide Film, Only One Side of which Exhibits Thermal Fusion Bondability)

First, a three-layered self-supporting film for constituting a layer (b) which exhibits thermal fusion bondability was produced. Using a film-forming device equipped with a die for three-layer extrusion molding (a multi-manifold type die), the dope for a heat-resistant polyimide and the dope for a thermal fusion bondable polyimide prepared above were casted over a metal support from the three-layer extrusion die in such a manner that (S2/S1/S2) were laminated, and the film was continuously dried by hot air at 140° C. and then peeled to form a self-supporting film.

After peeling this self-supporting film from the support, the coating solution 1 was applied to one side of the self-supporting film to a thickness of 0.5 μm. Then, it was gradually heated by hot air in a heating furnace from 150° C. to 450° C. for removing the solvent and initiating imidization to give a long polyimide film, which was winded on a roll.

The properties of the polyimide film thus obtained are shown in Table 1.

### Examples 2 to 12

A polyimide film was produced as described in Example 1, except that in a polyimide layer (b), both sides of which exhibited thermal fusion bondability, a thickness of each layer, a composition of a coating solution and a coating thickness were changed as shown in Table 1. The properties of the polyimide film obtained are shown in Table 1. A composition of each coating solution is shown in Table 2.

### Comparative Example 1

Using a coating solution 4 free from a-BPDA as shown in Table 1 as an acid component, a polyimide film was formed as described in Example 11 (see Table 1). During heating, foams were observed over the whole coating surface. Furthermore, the coating side of the resulting polyimide film did not exhibit thermal fusion bondability at all, so that a peel strength could not be determined. Although the cause of such foaming is not clearly understood, it would be because a polyimide formed from the coating solution 4 blocks a solvent and water vaporizing from the polyimide layer exhibiting thermal fusion bondability (b).

TABLE 1

| | Layer exhibiting | Layer not exhibiting | | | | |
|---|---|---|---|---|---|---|
| | thermal fusion | thermal fusion | | | | |
| | bondability (b) | bondability (a) | | | | |
| | Thickness | Coating | Coating | | | |
| | of each | solution | thickness | Visual | | Peeling |
| | layer (μm)* | composition | (μm) | observation | HAZE | property |
| Example 1 | 6/38/4 | 1 | 0.5 | Good | 7.37 | ∘∘ |
| Example 2 | 6/38/4 | 1 | 0.8 | Good | 7.41 | ∘∘ |
| Example 3 | 6/38/4 | 1 | 1.2 | Good | 7.41 | ∘∘ |
| Example 4 | 6/38/4 | 2 | 0.8 | Slightly | 9.01 | ∘∘ |
| | | | | devitrified | | |
| Example 5 | 6/38/4 | 1 | 0.8 | Good | 7.69 | ∘∘ |
| Example 6 | 6/38/4 | 2 | 1.2 | Slightly | 9.44 | Δ |
| | | | | devitrified | | |
| Example 7 | 2/8/2 | 1 | 0.5 | Good | 2.79 | Δ |
| Example 8 | 2/8/2 | 1 | 0.8 | Good | 3.35 | Δ |
| Example 9 | 2/8/2 | 1 | 1.2 | Good | 4.68 | Δ |
| Example 10 | 2/8/2 | 2 | 0.5 | Good | 4.45 | ∘ |
| Example 11 | 6/38.2/4.2 | 3 | 0.8 | Devitrified | 10.78 | ∘∘ |
| Example 12 | 2/8/2 | 3 | 0.5 | Devitrified | 11.5 | ∘ |
| Comparative | 6/38.2/4.2 | 4 | 0.8 | Overall | — | Not |
| Example 1 | | | | foaming | | evaluated |

*For three layers constituting the layer (b) exhibiting thermal fusion bondability, a thickness of each layer of (the thermal fusion bondable polyimide layer in the air side/the heat-resistant polyimide layer/the thermal fusion bondable polyimide layer in the belt side) was measured.

TABLE 2

| Coating solution | |
|---|---|
| composition | s-BPDA/a-BPDA/PPD |
| 1 | 0/5/5 |
| 2 | 2.5/2.5/5 |
| 3 | 3.75/1.25/5 |
| 4 | 5/0/5 |

The results of Examples and Comparative Example show the followings.

(1) A film appearance was good in Examples using 2,3,3′,4′-biphenyltetracarboxylic dianhydride (a-BPDA) as a tetracarboxylic dianhydride component of a layer (a) not exhibiting thermal fusion bondability. In contrast, in Comparative Example 1 free from a-BPDA, the film surface was in a foaming state. The fact that a-BPDA influences an appearance of a film surface is a totally novel finding.

(2) When a-BPDA was contained in 50 mol % or more in a tetracarboxylic dianhydride component for a layer (a) not exhibiting thermal fusion bondability, an appearance of a film surface was particularly good.

(3) When a layer (b) exhibiting thermal fusion bondability is thick, peeling property is better than a thin layer.

### INDUSTRIAL USABILITY

A polyimide film of the present invention and a laminate in which the polyimide film and a metal foil are laminated are useful as a material for an electronic component such as a printed circuit board.

### DESCRIPTION OF SYMBOLS

11: Polyimide layer (a) not exhibiting thermal fusion bondability
12: Polyimide layer (b) exhibiting thermal fusion bondability
12a: Heat-resistant polyimide layer (S1)
12b: Polyimide layer (S2) exhibiting thermal fusion bondability
13: Side not exhibiting thermal fusion bondability
14: Side exhibiting thermal fusion bondability
15: Clamp
16: Polyimide film
17: T-peel jig

1. A polyimide film comprising:
a polyimide layer (b), and
a polyimide layer (a) laminated in contact with said polyimide layer (b),
wherein
a side of said polyimide layer (b) which is not in contact with the polyimide layer (a) exhibits thermal fusion bondability,
a side of said polyimide layer (a) which is not in contact with the polyimide layer (b) does not exhibit thermal fusion bondability, and
said polyimide layer (a) comprises a polyimide formed from a tetracarboxylic acid component containing 2,3,3′,4′-biphenyltetracarboxylic dianhydride and a diamine component.

2. The polyimide film according to claim 1, wherein said polyimide layer (b) has a multi-layer structure having a thermal fusion bondable polyimide layer and a heat-resistant polyimide layer.

3. The polyimide film according to claim 1, wherein said polyimide layer (b) has a three-layer structure where the thermal fusion bondable polyimide layers are formed on both sides of the heat-resistant polyimide layer.

4. The polyimide film according to claim 1, wherein a content of 2,3,3′,4′-biphenyltetracarboxylic dianhydride in said tetracarboxylic acid component is 25 mol % or more.

5. The polyimide film according to claim 1, wherein a content of 2,3,3′,4′-biphenyltetracarboxylic dianhydride in said tetracarboxylic acid component is 50 mol % or more and 100 mol % or lower.

6. The polyimide film according to claim 2, wherein a total thickness of said polyimide layer (b) is 15 to 50 μm, a thickness of said heat-resistant polyimide layer is 10 to 40 μm, and a thickness of a single-layer in said thermal fusion bondable polyimide layer is 4 to 6 μm.

7. The polyimide film according to claim 2, wherein said heat-resistant polyimide layer is formed from an acid component comprising 3,3′,4,4′-biphenyltetracarboxylic dianhydride and a diamine component comprising p-phenylenediamine.

8. A polyimide-metal laminate wherein the polyimide film having the polyimide layer (b) according to claim 1 and a metal layer are laminated, and wherein the side exhibiting thermal fusion bondability of the polyimide layer (b) which is not in contact with the polyimide layer (a) directly contacts the metal layer.

9. A process for manufacturing a polyimide film, comprising:
producing a self-supporting film (b) by using a polyamic acid (b) for preparing a polyimide layer (b), both sides of which exhibits thermal fusion bondability;
applying a polyamic acid (a) obtained from an acid component comprising 2,3,3′,4′-biphenyltetracarboxylic dianhydride and a diamine component to only one side of said self-supporting film (b), to form a coated film; and
heating said coated film for imidization.
